(19) United States
(12) Patent Application Publication
(10) Pub. No.: US 2008/0128882 A1
(43) Pub. Date: Jun. 5, 2008

(54) CHIP STACK PACKAGE AND METHOD OF MANUFACTURING THE SAME

(75) Inventors: Seung-Duk BAEK, Gyeonggi-do (KR); Sun-Won KANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/949,523

(22) Filed: Dec. 3, 2007

(30) Foreign Application Priority Data
Dec. 5, 2006 (KR) 2006-121863

(51) Int. Cl. H01L 23/02; H01L 21/02

(52) U.S. Cl. 257/686; 438/109; 257/E23.172; 257/E21.575

(57) ABSTRACT

A chip stack package comprising an intermediate substrate having a recess, a first chip mounted in the recess, a second chip over the intermediate substrate, a package substrate formed under the intermediate substrate and first plugs through the intermediate substrate is disclosed. The second chip is configured to be electrically connected to the first chip. The first plugs are configured to electrically connect the second chip and the package substrate.

### CROSS-REFERENCE TO RELATED APPLICATIONS

This application claims priority under 35 U.S.C. § 119 to Korean Patent Application No. 2006-121863, filed on Dec. 5, 2006 in the Korean Intellectual Property Office (KIPO), the contents of which are incorporated herein by reference in their entirety.

### BACKGROUND

1. Technical Field

Example embodiments of the present invention relate to a chip stack package and a method of manufacturing the chip stack package.

2. Description of the Related Art

Currently, package stacking technology and chip stacking technology are used to enhance the degree of integration of semiconductor products. In the package stacking technology, packages are stacked using solder balls. In the chip stacking technology, semiconductor chips are stacked using plugs formed through a substrate.

In the chip stacking technology, a first chip usually serving as a memory device and a second chip usually serving as a logic device are electrically connected to each other, and the second chip is electrically connected to a package substrate. When the first chip is disposed between the second chip and the package substrate, a plug is formed through the first chip so as to electrically connect the second chip with the package substrate, and thus the first chip usually has a large size. The large size is required so that the plugs can be formed in areas of the semiconductor chip that do not include active circuitry. When the second chip is disposed between the first chip and the package substrate, heat generated from the second chip may not be easily dissipated, which may lead to premature failure of the device. Consequently, a need remains for a chip stacking technology that does not require a semiconductor chip to have a large size and that is able to adequately dissipate heat generated in the semiconductor chips.

### SUMMARY

Example embodiments of the present invention relate to a chip stack package including a first chip having a small size and a second chip in which heat generated therefrom may be easily dissipated. Example embodiments of the present invention also relate to a method of manufacturing the chip stack package including a first chip having a small size and a second chip in which heat generated therefrom may be easily dissipated.

According to one aspect of the present invention, a chip stack package is provided. The chip stack package may comprise an intermediate substrate having a recess, a first chip mounted in the recess, a second chip disposed on the intermediate substrate, a package substrate disposed under the intermediate substrate and first plugs through the intermediate substrate. The second chip is configured to be electrically connected to the first chip. The first plugs are configured to electrically connect the second chip and the package substrate.

According to some example embodiments of the present invention, the second chip and the package substrate may be electrically connected to each other through a plug formed through the intermediate substrate, so that the first chip may have a small size.

### BRIEF DESCRIPTION OF THE DRAWINGS

The above and other features and advantages of the present invention will become more apparent by describing in detailed example embodiments thereof with reference to the accompanying drawings, in which:

FIGS. 1 to 3 are cross-sectional views illustrating a chip stack package in accordance with some example embodiments of the present invention;

FIGS. 4A to 4E are cross-sectional views illustrating a method of manufacturing the chip stack package in FIG. 1 in accordance with some example embodiments of the present invention;

FIGS. 5A to 5E are cross-sectional views illustrating a method of manufacturing the chip stack package in FIG. 2 in accordance with some example embodiments of the present invention; and

FIGS. 6A to 6E are cross-sectional views illustrating a method of manufacturing the chip stack package in FIG. 3 in accordance with some example embodiments of the present invention.

### DETAILED DESCRIPTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, the present invention will be explained in detail with reference to the accompanying drawings.

FIG. 1 is a cross-sectional view illustrating a chip stack package in accordance with some example embodiments of the present invention.

Referring to FIG. 1, a chip stack package 100 includes an intermediate substrate 110, a plurality of plugs 120, a first chip 130, a second chip 140 and a package substrate 150.

A recess 112 is formed at a lower portion of the intermediate substrate 110. In an example embodiment of the present invention, the recess 112 is formed at a central lower portion of the package substrate 150. The intermediate substrate 110 may include an insulating material such as silicon (Si), gallium arsenide (GaAs), a ceramic material, etc.

The plugs 120 are formed through the intermediate substrate 110 and are spaced apart from each other. A plug pad 122 is formed at both ends of each of the plugs 120. The plug pad 122 may include a conductive material.

The first chip 130 is mounted in the recess 112. A plurality of first chip pads 132 is formed at upper portions of the first chip 130, which are active portions. Each of the first chip pads 132 correspond to each of the plugs 120, respectively. The first chip 130 is electrically connected to the second chip 140 only through those of a plurality of conductive bumps 160 and the plugs 120 that are disposed at portions of the intermediate substrate 110 vertically corresponding to the region where the recess 112 is formed. Signal pins (not shown) of the first chip 130 may be electrically connected to the plugs 120. The first chip 130 may include a memory device such as a dynamic random access memory (DRAM) device, a static random access memory (SRAM) device, a phase-change random access memory (PRAM) device, a ferroelectric random access memory (FRAM) device, a flash memory device, etc.

One first chip 130 mounted in the recess 112 of the intermediate substrate 110 is illustrated in FIG. 1; however, a plurality of the first chips 130 may be mounted in the recess 112 of the intermediate substrate 110. In this case, the first chips 130 may be vertically or horizontally mounted in the recess 112. Additionally, one wiring or a plurality of wirings may be formed in the intermediate substrate 110.

The second chip 140 is formed over the intermediate substrate 110. The second chip 140 may have a width larger than that of the first chip 130 and substantially the same as that of the intermediate substrate 110. A plurality of second chip pads 142 is formed at lower portions of the second chip 140, which are active portions. The second chip 140 may be electrically connected to the first chip 130 and the package substrate 150 through the plugs 120 and conductive bumps 160. The second chip 140 may be electrically connected to not only some of the plugs 120 that are electrically connected to the first chip 130 but also others of the plugs 120 that are not electrically connected to the first chip 130, because the second chip 140 has a width larger than that of the first chip 130. Thus, the first and second chips 130 and 140 may be electrically connected to each other through the plugs 120. Signal pins (not shown) of the second chip 140 may be electrically connected to the plugs 120. The second chip 140 may include a logic device such as a central processing unit (CPU), a controller, an application-specific integrated circuit (ASIC), etc.

The package substrate 150 is formed under the intermediate substrate 110. The package substrate 150 may have a width larger than that of the intermediate substrate 110. A plurality of substrate pads 152 is formed at upper portions of the package substrate 150 not vertically corresponding to the recess 112. Each of the substrate pads 152 correspond to each of the plugs 120 formed over the upper portions of the package substrate 150 not vertically corresponding to the recess 112. The package substrate 150 and the plugs 120 are electrically connected to each other through the conductive bumps 160. Thus, the second chip 140 may be electrically connected to the package substrate 150 through the plugs 120.

A plurality of external connection terminals 170 is formed on a lower face of the package substrate 150. The chip stack package may be connected to another substrate (not shown) through the external connection terminals 170. The external connection terminals 170 may be, for example, solder balls.

A radiator (not shown) may be disposed on the second chip 140 and dissipate heat generated from the second chip.

In the present embodiment, the signal pins of the first and second chips 130 and 140 are connected to the plugs 120. However, power pins or ground pins of the first and second chips 130 and 140 may be connected to the plugs 120, and thus may be connected to the package substrate 150. In this case, the power pins or the ground pins may be separated from the signal pins or merged with the signal pins.

The chip stack package 100 in accordance with some example embodiments of the present invention includes the first chip 130 mounted in the intermediate substrate 110, the second chip 140 electrically connected to the first chip 130 through some of the plugs 120, and the package substrate 150 electrically connected to the second chip 140 through others of the plugs 120. The plugs 120 are formed through the intermediate substrate 110, so that the first chip 130 may have a reduced width. Additionally, heat generated from the second chip 140 may be efficiently dissipated by the radiator because the second chip 140 is formed at an outer part of the chip stack package 100.

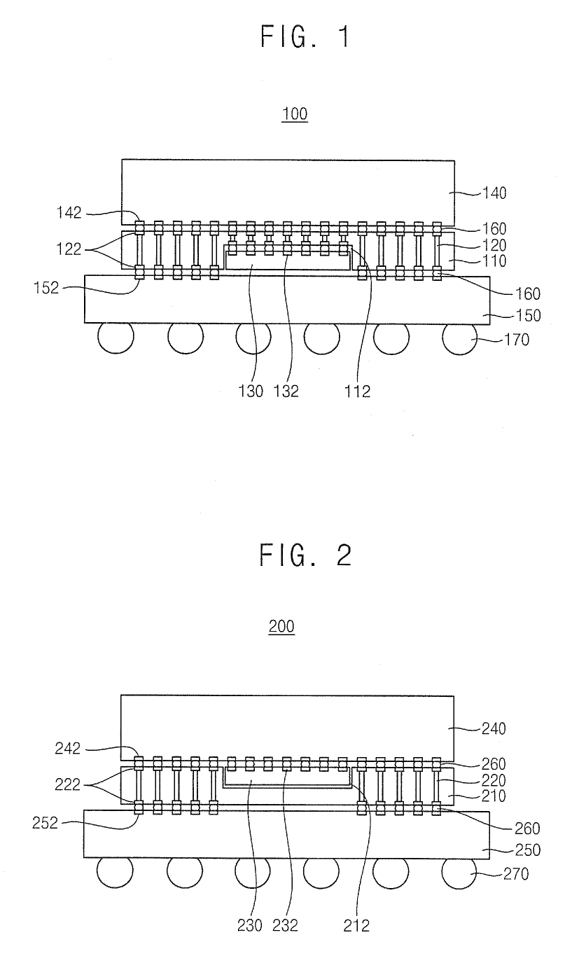

FIG. 2 is a cross-sectional view illustrating a chip stack package in accordance with other example embodiments of the present invention.

Referring to FIG. 2, a chip stack package 200 includes an intermediate substrate 210, a plurality of plugs 220, a first chip 230, a second chip 240 and a package substrate 250.

The chip stack package 200 is substantially the same as the chip stack package 100 in FIG. 1 except for the position of a recess 212 compared to the position of the recess 112 and a method of connecting the first chip 230 with the second chip 240 compared to the method of connecting the first chip 130 with the second chip 140.

The recess 212 is formed at an upper portion of the intermediate substrate 210. In an example embodiment of the present invention, the recess 212 is formed at a central upper portion of the intermediate substrate 210. A plurality of plugs 220 is formed through portions of the intermediate substrate 210 not vertically corresponding to the recess 212. The first and second chips 230 and 240 are not electrically connected to each other through the plugs 220 but instead the first and second chips 230 and 240 are electrically connected through a plurality of conductive bumps 260.

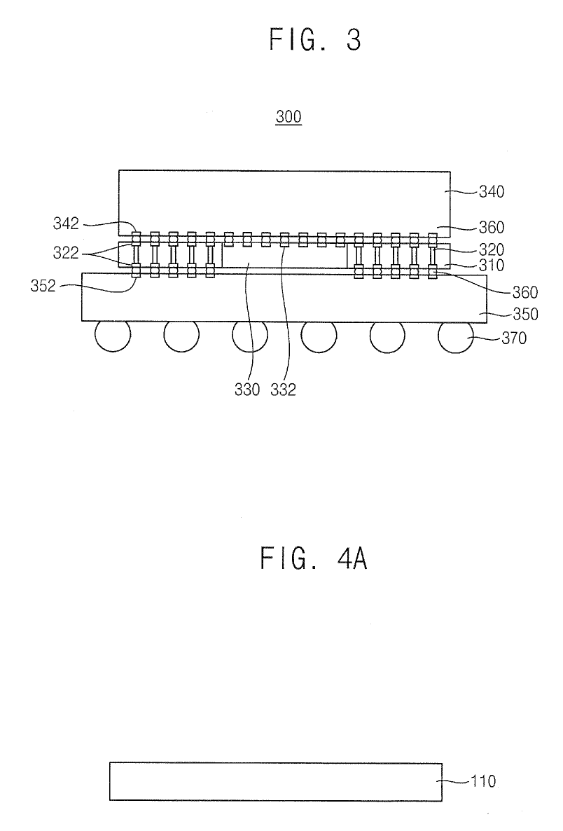

FIG. 3 is a cross-sectional view illustrating a chip stack package in accordance with still other example embodiments of the present invention.

Referring to FIG. 3, a chip stack package 300 includes an intermediate substrate 310, a plurality of plugs 320, a first chip 330, a second chip 340 and a package substrate 350.

The chip stack package 300 is substantially the same as the chip stack package 100 in FIG. 1 except for the shape of the intermediate substrate 310 compared to the shape of the intermediate substrate 110 and a method of connecting the first chip 330 with the second chip 340 compared to the method of connecting the first chip 130 with the second chip 140.

The intermediate substrate 310 substantially surrounds a sidewall of the first chip 330. The first and second chips 330 and 340 are not electrically connected to each other through the plugs 320 but instead the first and second chips 330 and 340 are electrically connected through a plurality of conductive bumps 360.

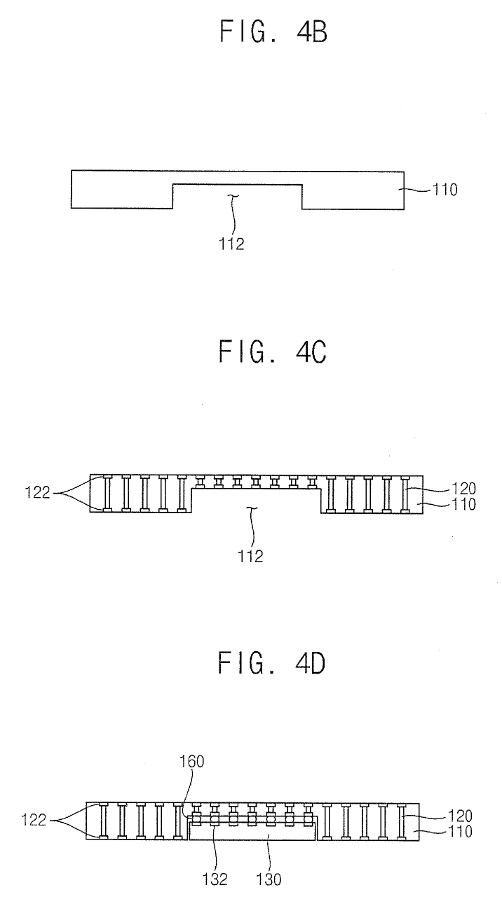

FIGS. 4A to 4E are cross-sectional views illustrating a method of manufacturing the chip stack package 100 in FIG. 1 in accordance with some example embodiments of the present invention.

Referring to FIG. 4A, an intermediate substrate 110 is prepared.

The intermediate substrate 110 may be formed using an insulating material such as silicon (Si), gallium arsenide (GaAs), a ceramic material, etc.

Referring to FIG. 4B, a recess 112 is formed at a lower portion of the intermediate substrate 110. The recess 112 may be formed at a central lower portion of the intermediate substrate 110.

Specifically, after forming a first mask on a lower face of the intermediate substrate 110, the lower portion of the intermediate substrate 110 may be anisotropically etched to form the recess 112 using the first mask as an etching mask. Alternatively, the lower portion of the intermediate substrate 110 may be etched to form the recess 112 by a laser etching process.

Referring to FIG. 4C, a plurality of plugs 120 is formed through the intermediate substrate 110, and a plurality of plug pads 122 is formed at both ends of the plugs 120, respectively.

In particular, a second mask is formed on an upper face of the intermediate substrate 110. Some portions of the intermediate substrate 110 may be anisotropically etched to form a plurality of holes through the intermediate substrate 110 using the second mask as an etching mask. Alternatively, the plurality of holes may be formed by a laser drilling technique. A conductive material is deposited in the holes to fill up the holes, thereby forming the plugs 120. The holes may be filled up with the conductive material by a deposition process, an electroplating process, etc. After forming a third mask and a fourth mask on the upper and lower faces, respectively, some portions of the intermediate substrate 110 are anisotropically etched to form openings exposing the plugs 120 at upper and lower portions using the third and fourth masks as etching masks. The openings may be filled with a conductive material to form the plug pads 122.

Referring to FIG. 4D, a first chip 130 is mounted in the recess 112 of the intermediate substrate 110 and is electrically connected to the plugs 120.

Specifically, a plurality of first chip pads 132 is formed at upper portions of the first chip 130 corresponding to the plugs 120, respectively. The first chip pads 132 may be formed by a process substantially the same as that for forming the plug pads 122. A plurality of conductive bumps 160 is formed on the first chip pads 132, respectively. In an example embodiment of the present invention, the conductive bumps 160 may be formed by a deposition process using a stencil mask. Alternatively, the conductive bumps 160 may be formed by an electroplating process, etc. The first chip 130 is inserted into the recess 112 and compressed, so that the first chip pads 132 and the plug pads 122 may be electrically connected to each other through the conductive bumps 160, respectively. Compressing the first chip 130 may include heating the first chip 130, the intermediate substrate 110, and/or the conductive bumps 160.

Referring to FIG. 4E, a second chip 140 electrically connected to the plugs 120 is formed over the intermediate substrate 110, and a package substrate 150 electrically connected to the plugs 120 is formed under the intermediate substrate 110.

Particularly, a plurality of second chip pads 142 corresponding to the plugs 120, respectively, is formed at lower portions of the second chip 140, which are active portions. The second chip may have a width larger than that of the first chip 130. The second chip pads 142 may be formed by a process substantially the same as that for forming the plug pads 122. A plurality of conductive bumps 160 is formed on the second chip pads 142, respectively. While the conductive bumps 160 make contact with the plug pads 122 on the plugs 120, respectively, the second chip 140 is compressed, so that the second chip pads 142 and the plug pads 122 may be electrically connected to each other through the conductive bumps 160, respectively. Compressing the second chip 140 may include heating the second chip 140, the intermediate substrate 110, and/or the conductive bumps 160.

A plurality of substrate pads 152 is formed at upper portions of the package substrate 150 not vertically corresponding to the recess 112. The package substrate 150 may have a width larger than or substantially the same as that of the second chip 140. The substrate pads 152 may correspond to the plugs 120, respectively. The substrate pads 152 may be formed by a process substantially the same as that for forming the plug pads 122. A plurality of conductive bumps 160 is formed on the substrate pad 152, respectively. While the conductive bumps 160 make contact with the plug pads 122 beneath the plugs 120, respectively, the package substrate 150 is compressed, so that the substrate pads 152 and the plug pads 122 may be electrically connected to each other through the conductive bumps 160, respectively. Compressing the package substrate 150 may include heating the package substrate 150, the intermediate substrate 110, and/or the conductive bumps 160. Thus, the package substrate 150 and the plugs 120 may be electrically connected to each other. A plurality of external connection terminals 170 is formed on a lower face of the package substrate 150. Another substrate (not shown) may be electrically connected to the chip stack package 100 through the external connection terminals 170.

A radiator (not shown) may be disposed on the second chip 140 and dissipate heat generated from the second chip 140.

The chip stack package 100 in accordance with some example embodiments of the present invention includes the first chip 130 mounted in the intermediate substrate 110, the second chip 140 electrically connected to the first chip 130 through some of the plugs 120, and the package substrate 150 electrically connected to the second chip 140 through others of the plugs 120. The plugs 120 are formed through the intermediate substrate 110, so that the first chip 130 may have a reduced width. Additionally, heat generated from the second chip 140 may be efficiently dissipated by the radiator because the second chip 140 is formed at an outer part of the chip stack package 100.

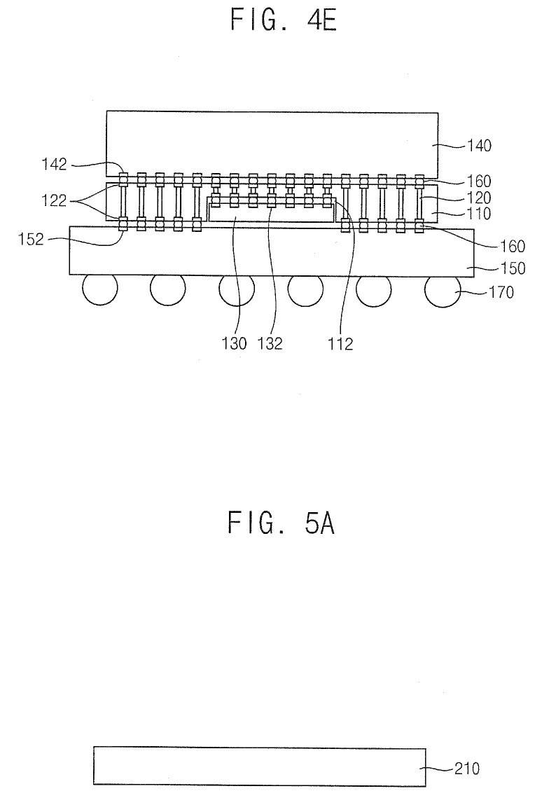

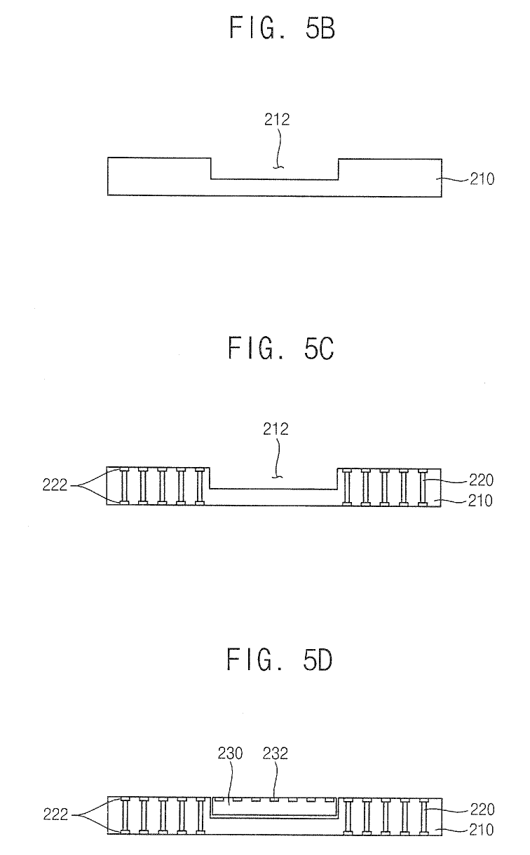

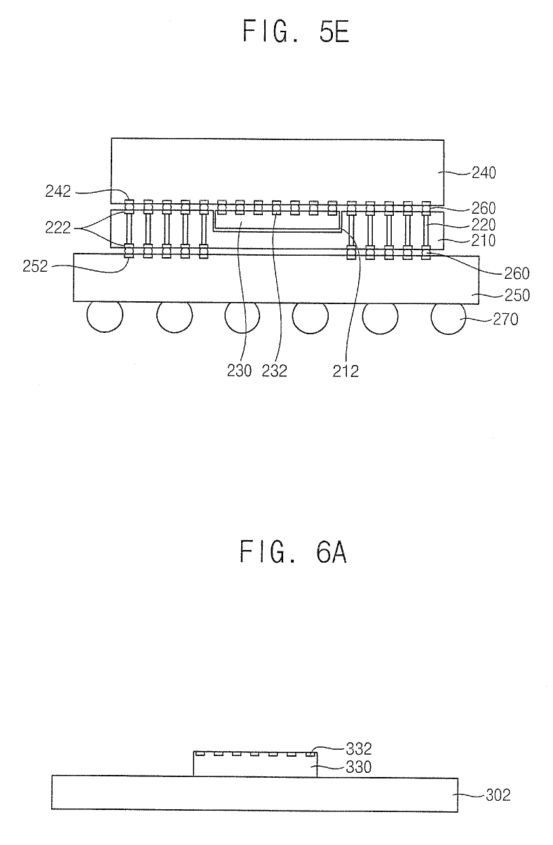

FIGS. 5A to 5E are cross-sectional views illustrating a method of manufacturing the chip stack package 200 in FIG. 2 in accordance with some example embodiments of the present invention.

Referring to FIGS. 5A to 5C, a process for forming a recess 212 is substantially the same as that for forming the recess 112 illustrated in FIG. 4B, except that the recess 212 is formed on an upper portion of the intermediate substrate 210. Additionally, processes for forming a plurality of plugs 220 and a plurality of plug pads 222 are substantially the same as those for forming the plugs 120 and the plug pads 122, respectively, illustrated in FIG. 4C except that the plugs 220 and the plug pads 222 are formed through only portions of the intermediate substrate 210 not vertically corresponding to the recess 212.

Referring to FIG. 5D, a first chip 230 is mounted in the recess 212 of the intermediate substrate 210. Specifically, a plurality of first chip pads 232 is formed at upper portions of the first chip 230, which are active portions. The first chip pads 232 may be disposed at a predetermined distance from each other. The first chip pads 232 may be formed by a process substantially the same as that for forming the plug pads 222. The first chip 230 having the chip pads 232 directed upward is inserted into the recess 212.

Referring to FIG. 5E, a second chip 240, electrically connected to the plugs 220 and the first chip 230, is formed over the intermediate substrate 210, and the package substrate 250, electrically connected to the plugs 220, is formed under the intermediate substrate 210.

In particular, a plurality of second chip pads 242 corresponding to the plugs 220, respectively, is formed at lower portions of the second chip 240, which are active portions. The second chip 240 may have a width larger than that of the first chip 230. The second chip pads 242 may be formed by a process substantially the same as that for forming the plug pads 222. A plurality of conductive bumps 260 is formed on the second chip pads 242, respectively. While the conductive bumps 260 make contact with the plug pads 222 on the plugs 220, respectively, the second chip 240 is compressed, so that the second chip pads 242 may be electrically connected to the plug pads 222 and the first chip pads 232 through the conductive bumps 260, respectively. Compressing the second chip 240 may include heating the second chip 240, the intermediate substrate 210, the first chip 230, and/or the conductive bumps 260. Thus, the second chip 240 may be electrically connected to the plugs 220 and the first chip 230.

A process of mounting the package substrate 250 is substantially the same as that of mounting the package substrate 150 illustrated in FIG. 4E.

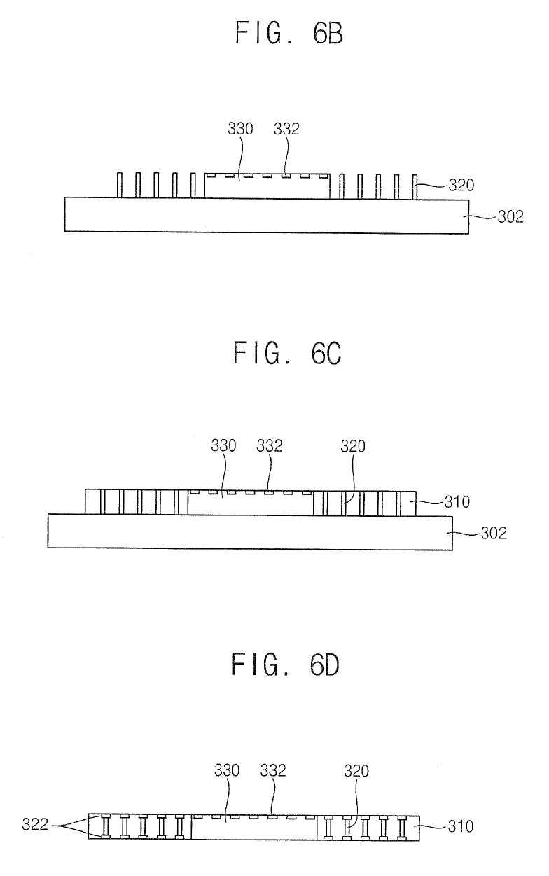

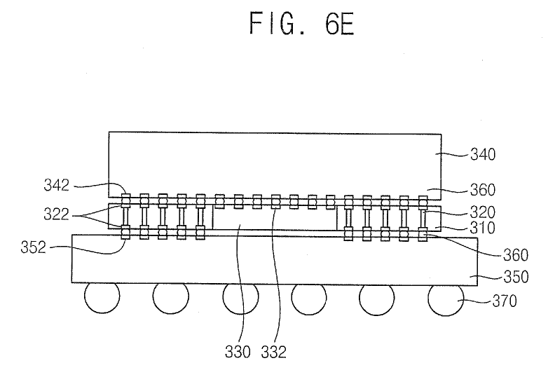

FIGS. 6A to 6E are cross-sectional views illustrating a method of manufacturing the chip stack package 300 in FIG. 3 in accordance with some example embodiments of the present invention.

Referring to FIG. 6A, a first chip 330 is formed on a sacrificial substrate 302. Specifically, the sacrificial substrate 302 may include an insulating material such as a polymeric material, silicon (Si), gallium arsenide (GaAs), a ceramic material, etc. A mask is formed on an upper face of the first chip 330. Upper portions of the first chip 330 are anisotropically etched to form a plurality of grooves on the first chip 330 using the mask as an etching mask. A conductive material is deposited in the grooves to fill up the grooves, thereby forming a plurality of first chip pads 332. The first chip 330 having the first chip pads 332 directed upward is attached onto the sacrificial substrate 302.

Referring to FIG. 6B, a plurality of plugs 320 is formed on upper portions of the sacrificial substrate 302 that do not make contact with the first chip 330. Each of the plugs 320 may be formed to have a vertical pillar shape.

In an example embodiment of the present invention, a photoresist layer (not shown) is formed on the sacrificial substrate 302. The photoresist layer may have a height substantially the same as that of the first chip 330. The photoresist layer may be partially removed by an exposure process and a developing process to form a plurality of holes exposing the sacrificial substrate 302 through the photoresist layer. The holes may be filled up with a conductive material to form the plugs 320 by a deposition process, an electroplating process, a stencil process, etc. The photoresist layer may be removed to expose the plugs 320 by an ashing process, etching process, etc.

In another example embodiment of the present invention, a sacrificial layer (not shown) is formed on the sacrificial substrate 302. The sacrificial layer may be formed using an insulating material. The sacrificial layer may have a height substantially the same as that of the first chip 330. A mask is formed on an upper face of the first chip 330 and the sacrificial layer. The sacrificial layer may be partially removed by an anisotropic etching process to form a plurality of holes using the mask as an etching mask. The holes may be filled up with a conductive material to form the plugs 320 by a deposition process, an electroplating process, a stencil process, etc. The sacrificial layer may be removed by a wet etching process to expose the plugs 320.

Referring to FIG. 6C, an intermediate substrate 310 is formed on the sacrificial substrate 302 enclosing sidewalls of the first chip 330 and the plugs 320.

In particular, an insulating material is deposited on the sacrificial substrate 302 to enclose the sidewalls of the first chip 330 and the plugs 320. The insulating material may be deposited on the sacrificial substrate 302 to have a height substantially the same as that of the first chip 330. Examples of the insulating material may include a polymeric material, silicon (Si), gallium arsenide (GaAs), a ceramic material, etc. The insulating material may be hardened to form the intermediate substrate 310.

Referring to FIG. 6D, a plurality of plug pads 322 is formed at both ends of the plugs 320.

Specifically, the sacrificial substrate 302 is removed from the intermediate substrate 310 and the first chip 330. A mask is formed on an upper face and a lower face of the intermediate substrate 310. Upper portions and lower portions of the intermediate substrate 310 are removed to form openings exposing the plugs 320 by an anisotropic etching process using the masks as an etching mask. The openings may be filled with a conductive material to form the plug pads 322.

Referring to FIG. 6E, a second chip 340, electrically connected to the plugs 320, is formed on the intermediate substrate 310. A package substrate 350, electrically connected to the plugs 320, is formed under the intermediate substrate 310.

A process of mounting the second chip 340 and a process of mounting the package substrate 350 are substantially the same as that of mounting the second chip 140 and that of mounting the package substrate 150 illustrated in FIG. 4E.

In the present embodiment, after the plugs 320 are formed on the sacrificial substrate 302, the intermediate substrate 310 enclosing the sidewalls of the first chip 330 and the plugs 320 are formed. However, the plugs 320 may be formed through the intermediate substrate 310 after forming the intermediate substrate 310 enclosing the sidewall of the first chip 330 on the sacrificial substrate 302.

According to some example embodiments of the present invention, a second chip is formed over a first chip to be electrically connected to the first chip, and a package substrate is formed under the first chip to be electrically connected to the second chip through plugs, which are not formed through the first chip but through portions of an intermediate substrate. Thus, productivity in manufacturing the first chip may be improved because the plugs are not formed through the first chip so that the first chip may have a relatively small width. Additionally, heat generated from the second chip may be efficiently dissipated by a radiator because the second chip is formed over the first chip.

According to one aspect of the present invention, a chip stack package is provided. The chip stack package may comprise an intermediate substrate having a recess, a first chip mounted in the recess, a second chip disposed on the intermediate substrate, a package substrate disposed under the intermediate substrate and first plugs through the intermediate substrate. The second chip is configured to be electrically connected to the first chip. The first plugs are configured to electrically connect the second chip and the package substrate.

In some example embodiments, the recess may be formed at a lower portion of the intermediate substrate, and the first and second chips may be electrically connected to each other through second plugs.

In some example embodiments, the chip stack package may further comprise first conductive bumps configured to electrically connect the first plugs and the package substrate, second conductive bumps configured to electrically connect the first plugs and the second chip, third conductive bumps configured to electrically connect the second plugs and the first chip, and fourth conductive bumps configured to electrically connect the second plugs and the second chip.

In some example embodiments, the recess may be formed at an upper portion of the intermediate substrate. The chip stack package may further comprise first conductive bumps configured to electrically connect the first plugs and the package substrate, second conductive bumps configured to electrically connect the first plugs and the second chip, and third conductive bumps configured to electrically connect the second plugs and the first chip.

In some example embodiments, the first chip may include a memory device and the second chip may include a logic device.

In some example embodiments, the second chip may have a width larger than that of the first chip.

According to one aspect of the present invention, a method of manufacturing a chip stack package is provided. A recess is formed at a lower portion of an intermediate substrate. First plugs and second plugs are formed through the intermediate substrate. A first chip is mounted in the recess of the intermediate substrate to be electrically connected to the first plugs. A second chip is mounted on the intermediate substrate to be electrically connected to the first plugs. A package substrate is mounted under the intermediate substrate to be electrically connected to the first plugs.

In some example embodiments, the second chip may have a width larger than that of the first chip.

In some example embodiments, the first plugs may be formed through portions of the intermediate substrate not vertically corresponding to the recess.

In some example embodiments, the first plugs and the package substrate, the first plugs and the second chip, the second plugs and the first chip, and the second plugs and the second chip may be electrically connected to each other, respectively, through a plurality of conductive bumps.

According to another aspect of the present invention, a method of manufacturing a chip stack package is provided. A recess is formed at an upper portion of an intermediate substrate. Plugs are formed through portions of the intermediate substrate not vertically corresponding to the recess. A first chip is mounted in the recess. A second chip is mounted on the intermediate substrate to be electrically connected to the first chip. A package substrate is mounted under the intermediate substrate to be electrically connected to the plugs.

In some example embodiments, the second chip may have a width larger than that of the first chip.

In some example embodiments, the first chip and the second chip, the plugs and the second chip, and the plugs and the package substrate may be electrically connected to each other, respectively, through a plurality of conductive bumps.

According to another aspect of the present invention, a method of manufacturing a chip stack package is provided. A first chip is attached on a sacrificial substrate. Plugs are formed on upper portions of the sacrificial substrate that do not make contact with the first chip. The plugs extend in a direction substantially perpendicular to the sacrificial substrate. An intermediate substrate is formed on the sacrificial substrate. The intermediate substrate encloses sidewalls of the first chip and the plugs. The sacrificial substrate is removed. A second chip is mounted on the intermediate substrate to be electrically connected to the plugs and the first chip. A package substrate is mounted under the intermediate substrate to be electrically connected to the plugs.

In some example embodiments, the second chip may have a width larger than that of the first chip.

In some example embodiments, the first chip and the second chip, the plugs and the second chip, and the plugs and the package substrate may be electrically connected to each other, respectively, through a plurality of conductive bumps.

According to some example embodiments of the present invention, the second chip and the package substrate may be electrically connected to each other through a plug formed through the intermediate substrate, so that the first chip may have a small size.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A chip stack package, comprising:
an intermediate substrate having a recess;
a first chip mounted in the recess;
a second chip disposed on the intermediate substrate, the second chip configured to be electrically connected to the first chip;
a package substrate disposed under the intermediate substrate; and
first plugs through the intermediate substrate, the first plugs configured to electrically connect the second chip and the package substrate.

2. The chip stack package of claim 1, wherein the recess is disposed at a lower portion of the intermediate substrate, and the first and second chips are electrically connected to each other through second plugs.

3. The chip stack package of claim 2, further comprising first conductive bumps configured to electrically connect the first plugs and the package substrate, second conductive bumps configured to electrically connect the first plugs and the second chip, third conductive bumps configured to electrically connect the second plugs and the first chip, and fourth conductive bumps configured to electrically connect the second plugs and the second chip.

4. The chip stack package of claim 1, wherein the recess is formed at an upper portion of the intermediate substrate.

5. The chip stack package of claim 4, further comprising first conductive bumps configured to electrically connect the first plugs and the package substrate, second conductive bumps configured to electrically connect the first plugs and the second chip, and third conductive bumps configured to electrically connect the first chip and the second chip.

6. The chip stack package of claim 1, wherein the first chip includes a memory device and the second chip includes a logic device.

7. The chip stack package of claim 1, wherein the second chip has a width larger than that of the first chip.

8. A chip stack package, comprising:
a first chip;
an intermediate substrate substantially surrounding sidewalls of the first chip, the intermediate substrate including a plurality of plugs;
a second chip disposed on the intermediate substrate and the first chip, wherein the second chip is electrically connected to the first chip; and
a package substrate disposed under the intermediate substrate and electrically connected to the second chip through the plurality of plugs.

9. The chip stack package of claim 8, further comprising first conductive bumps configured to electrically connect the plugs and the package substrate, second conductive bumps configured to electrically connect the plugs and the second chip, and third conductive bumps configured to electrically connect the first chip and the second chip.

10. The chip stack package of claim 8, further comprising a plurality of external connection terminals disposed on the package substrate.

11. A method of manufacturing a chip stack package, comprising:
forming a recess at a lower portion of an intermediate substrate;
forming first plugs and second plugs through the intermediate substrate;
mounting a first chip in the recess to be electrically connected to the second plugs;
mounting a second chip on the intermediate substrate to be electrically connected to the first plugs; and
mounting a package substrate under the intermediate substrate to be electrically connected to the first plugs.

12. The method of claim 11, wherein the second chip has a width larger than that of the first chip.

13. The method of claim 11, wherein the first plugs are formed through portions of the intermediate substrate not vertically corresponding to the recess.

14. The method of claim 11, wherein the first plugs and the package substrate, the first plugs and the second chip, the second plugs and the first chip, and the second plugs and the second chip are electrically connected to each other, respectively, through a plurality of conductive bumps.

15. A method of manufacturing a chip stack package, comprising:
forming a recess at an upper portion of an intermediate substrate;
forming plugs through portions of the intermediate substrate not vertically corresponding to the recess;
mounting a first chip in the recess;
mounting a second chip on the intermediate substrate to be electrically connected to the first chip; and
mounting a package substrate under the intermediate substrate to be electrically connected to the plugs.

16. The method of claim 15, wherein the second chip has a width larger than that of the first chip.

17. The method of claim 15, wherein the first chip and the second chip, the plugs and the second chip, and the plugs and the package substrate are electrically connected to each other, respectively, through a plurality of conductive bumps.

18. A method of manufacturing a chip stack package, comprising:
attaching a first chip on a sacrificial substrate;
forming plugs on upper portions of the sacrificial substrate that do not make contact with the first chip, the plugs extending in a direction substantially perpendicular to the sacrificial substrate;
forming an intermediate substrate on the sacrificial substrate, the intermediate substrate enclosing sidewalls of the first chip and the plugs;
removing the sacrificial substrate;
mounting a second chip on the intermediate substrate to be electrically connected to the plugs and the first chip; and
mounting a package substrate under the intermediate substrate to be electrically connected to the plugs.

19. The method of claim 18, wherein the second chip has a width larger than that of the first chip.

20. The method of claim 18, wherein the first chip and the second chip, the plugs and the second chip, and the plugs and the package substrate are electrically connected to each other, respectively, through a plurality of conductive bumps.
